(19) United States
(12) Patent Application Publication
(10) Pub. No.: US 2026/0304995 A1
(43) Pub. Date: Oct. 1, 2026

(54) PACKAGE STRUCTURE

(71) Applicant: Ennostar Corporation, Hsinchu City (TW)

(72) Inventors: Ming-Jing LEE, Hsinchu (TW); Markus OBERASCHER, Hsinchu (TW)

(21) Appl. No.: 19/636,461

(22) Filed: Apr. 1, 2026

(30) Foreign Application Priority Data
Apr. 1, 2025 (TW) 114112529

(51) Int. Cl. H10F 55/00; H10F 39/90; H10F 77/40; H10F 77/50; H10H 29/20; H10H 29/853; H10H 29/855; H10H 29/01; H10W 90/10; H10W 90/28

(52) U.S. Cl. CPC H10F 55/00; H10F 39/90; H10F 77/407; H10F 77/50; H10H 29/20; H10H 29/853; H10H 29/8552; H10H 29/0362; H10H 29/0363; H10W 90/10; H10W 90/28

(57) ABSTRACT

A package structure is provided. The package structure includes a substrate, an integrated circuit, a light-emitting element, a light-receiving element, a first light-blocking part, a second light-blocking part, and an encapsulation body. The integrated circuit is disposed on the substrate. The light-emitting element is disposed on the substrate and has a light-emitting surface. The light-receiving element is disposed on the integrated circuit and has a light-receiving surface. The first light-blocking part is disposed on the integrated circuit and between the light-emitting surface of the light-emitting element and the light-receiving surface of the light-receiving element. The second light-blocking part is disposed on the first light-blocking part. The encapsulation body is disposed on the light-emitting element and the light-receiving element.

### CROSS REFERENCE TO RELATED APPLICATIONS

This Application claims priority of Taiwan Patent Application No. 114112529, filed on April 1, 2025, the entirety of which is incorporated by reference herein.

### BACKGROUND OF THE DISCLOSURE

### Field of the Invention

The present disclosure relates to semiconductor technology. In particular, it relates to a package structure.

### Description of the Related Art

Optical sensing devices are widely used in electronic products, such as heart rate detection devices, distance detection devices, and optical sensing devices. Generally, the structure of an optical sensing package includes a light-emitting element and a light-receiving element. To avoid mutual interference between the light-emitting element and the light-receiving element, a shielding component is provided between the light-emitting element and the light-receiving element to separate them from each other.

As electronic products continue to evolve toward compact and lightweight designs, the size of optical sensing devices are became smaller. However, forming the shielding component using dicing, dispensing, molding, assembly, and other suitable processes imposes limitations on the potential for miniaturization of the package structure and the optical sensing device including the same. Although existing package structures and optical sensing devices met the intended purposes gradually, they do not perfect in all respects. There are still some issues to be overcome regarding package structures.

### BRIEF SUMMARY OF THE PRESENT DISCLOSURE

In some embodiments, a package structure is provided. The package structure includes a substrate, an integrated circuit, a light-emitting element, a light-receiving element, a first light-blocking part, a second light-blocking part, and an encapsulation body. The integrated circuit is disposed on the substrate. The light-emitting element is disposed on the substrate and has a light-emitting surface. The light-receiving element is disposed on the integrated circuit and has a light-receiving surface. The first light-blocking part is disposed on the integrated circuit and between the light-emitting surface of the light-emitting element and the light-receiving surface of the light-receiving element. The second light-blocking part is disposed on the first light-blocking part. The encapsulation body is disposed on the light-emitting element and the light-receiving element.

The package structure of the present disclosure may be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that in accordance with the standard practice in the industry, various features are not drawn to scale. In fact, the dimensions of the various features may be arbitrarily increased or reduced for clarity of discussion.

FIGS. 1 to 5 are respectively perspective schematic views illustrating the package structure at different formation stages according to some embodiments of the present disclosure.

FIGS. 6A and 6B are respectively a cross-sectional view and another cross-sectional view illustrating the package structure according to other embodiments of the present disclosure.

FIGS. 7A and 7B are respectively a cross-sectional schematic view and another cross-sectional schematic view illustrating the package structure according to other embodiments of the present disclosure.

FIGS. 8A and 8B are respectively a cross-sectional schematic view and another cross-sectional schematic view illustrating the package structure according to other embodiments of the present disclosure.

FIGS. 9A to 9C are respectively a perspective schematic views, a side schematic diagram, and a top schematic diagram illustrating the package structure according to further embodiments of the present disclosure.

FIG. 10 is a perspective schematic diagram illustrating the package structure according to another embodiment of the present disclosure.

FIG. 11 is a perspective schematic view illustrating the package structure according to another embodiment of the present disclosure.

FIG. 12 is a perspective schematic view illustrating the package structure according to another embodiment of the present disclosure.

FIG. 13 is a perspective schematic view illustrating the package structure according to another embodiment of the present disclosure.

### DETAILED DESCRIPTION OF THE PRESENT DISCLOSURE

The following disclosure provides many different embodiments or examples for implementing the provided device. Specific examples of various components and their configurations are described below to simplify the embodiments of the present disclosure, but are certainly not intended to limit the present disclosure. For example, if the description mentions that a first component is formed on a second component, it may include an embodiment in which the first component and the second component are in direct contact, and it may also include an embodiment in which an additional component is formed between the first component and the second component so that the first component and the second component are not in direct contact. Furthermore, the present disclosure may repeat element numerals and/ or characters in different embodiments or examples. This repetition is for the purpose of brevity and clarity and is not intended to indicate a relationship between the various embodiments and/or examples discussed.

In some embodiments of the present disclosure, terms such as “disposed”, “connected” and the like, unless otherwise defined, may refer to two components being in direct contact, or may refer to two components not being in direct contact, with an additional junction component located between the two structures. Terms related to being arranged and connected may also include situations where both structures are movable, or both structures are fixed.

In addition, the terms "first", "second" and similar terms mentioned in this specification or the scope of the patent application are used to name different components or distinguish different embodiments or scopes, and are not used to limit the upper or lower limit of the number of components, nor are they used to limit the manufacturing order or setting order of the components.

As used herein, the terms “approximate,” “about,” and “substantially” generally mean within 10%, or within 5%, or within 3%, or within 2%, or within 1%, or within 0.5% of a given value or range. The quantities given here are approximate quantities, that is, even if there is no specific description of "about", "approximately", or "substantially", the meanings of "about", "approximately", or "substantially" may still be implied. The term " a range between a first value and a second value " means that the range includes the first value, the second value, and other values therebetween. Furthermore, there may be a certain error between any two values or directions used for comparison. If a first value is equal to a second value, it implies that there may be an error of about 10%, or within 5%, or within 3%, or within 2%, or within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, for the sake of clarity, some elements of the device are omitted in the drawings, and only some elements are schematically illustrated. In some embodiments, additional components may be added to the devices described below. In other embodiments, some of the components of the apparatus described below may be replaced or omitted. It should be understood that in some embodiments, additional operating steps may be provided before, during and/or after the device manufacturing method. In some embodiments, some of the operation steps described may be replaced or omitted, and the order of some of the operation steps described may be interchangeable.

Unless otherwise defined, all terms (including technical and scientific terms) used herein have the same meanings as commonly understood by those of ordinary skill in the art. It is understood that these terms, such as those defined in commonly used dictionaries, should be interpreted as having a meaning consistent with the background or context of the relevant technology and the present disclosure, and should not be interpreted in an idealized or overly formal manner unless specifically defined in the embodiments of the present disclosure.

In some existing package structures, in order to prevent interference between the light-emitting function and the light-receiving function, a relatively large space is reserved within the package structure for placing the light-emitting element and the light-receiving element. This design causes the whole size of the package structure to be significantly larger than the individual sizes of the light-emitting element and the light-receiving element. Additionally, in the existing package structure, a shielding component may be disposed between the light-emitting element and the light-receiving element to reduce signal crosstalk. For example, a dicing process, a dispensing process, a molding process, an assembly process, or other suitable processes may be performed between the light-emitting element and the light-receiving element of the package structure to form the shielding component. In order to avoid damaging the light-emitting element or the light-receiving element during the dicing process, a specific distance must be maintained between the dicing region and each of the light-emitting and light-receiving elements. However, such a method not only limits the miniaturization of the package structure but also increases the manufacturing cost. To this end, the present disclosure provides a package structure, which reduces the specific distance required between the dicing region and the light-emitting element and the light-receiving element by providing a sacrificial layer or a barrier layer, thereby simplifying the manufacturing process and reducing the component size.

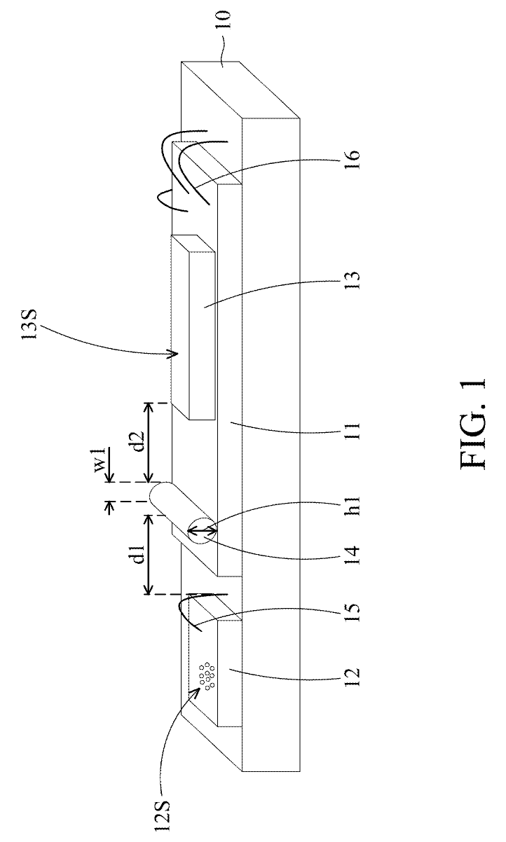

FIGS. 1 to 5 are perspective schematic diagrams illustrating the different formation stages of package structure according to some embodiments of the present disclosure. As shown in FIG. 1, a substrate 10 is provided. Specifically, the substrate 10 is configured to carry components, such as an integrated circuit 11, a light-emitting element 12, a light-receiving element 13, and other suitable components, the present disclosure is not limited thereto. In some embodiments, the substrate 10 may further serve to electrically connect the integrated circuit 11, the light-emitting element 12, and/or the light-receiving element 13 to other components (for example, a control unit or a voltage source, not shown). For example, the substrate 10 may electrically connect one or more of the integrated circuit 11, the light-emitting element 12, and the light-receiving element 13. In some embodiments, the substrate 10 may be or may include a circuit board. For example, the circuit board may be a rigid circuit board, a flexible circuit board, a printed circuit board, a combination thereof, or other suitable circuit boards. In some embodiments, the substrate 10 may be a single-layer structure or a multi-layer structure.

In some embodiments, the substrate 10 includes a dielectric layer and a circuit pattern located in or on the dielectric layer. In some embodiments, the dielectric layer may include epoxy resin, polyimide (PI), phenol formaldehyde resins (PF), bismaleimide triazine resin (BT resin), glass fiber, carbon fiber, epoxy glass cloth, other suitable materials, or a combination thereof, but the present disclosure is not limited thereto. In some embodiments, the circuit pattern may include metal, metal compound, other suitable conductive material, or a combination thereof. For example, the metal may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), germanium (Ge), or alloys thereof, but the present disclosure is not limited thereto. For example, the metal compound may be tantalum nitride (TaN), titanium nitride (TiN), tungsten silicide (WSi₂), indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO), indium zinc oxide (IZO) or indium gallium zinc oxide (IGZO), but the present disclosure is not limited thereto.

As shown in FIG. 1, continuing from the above steps, an integrated circuit 11 is disposed on the substrate 10. Specifically, the integrated circuit 11 may be configured to control one or both of the light-emitting element 12 and the light-receiving element 13, or to electrically connect the light-emitting element 12, the light-receiving element 13 to other electronic components, but the present disclosure is not limited thereto. In some embodiments, the integrated circuit 11 covers a portion of the substrate 10 and exposes another portion of the substrate 10. In this case, the light-emitting element 12 may be disposed on a portion of the substrate 10 that is not covered by the integrated circuit 11, and the light-receiving element 13 is disposed on the integrated circuit 11 or integrated into the integrated circuit 11. In some embodiments, the integrated circuit 11 includes a dielectric layer and a circuit pattern located in or on the dielectric layer. The materials of the dielectric layer and the circuit pattern may refer to the examples described above and will not be repeated here.

As shown in FIG. 1, continuing from the above steps, a light-emitting element 12 is disposed on the substrate 10, wherein the light-emitting element 12 has a light-emitting surface 12S. Specifically, the light-emitting element 12 is configured to emit light, and the light leaves the light-emitting element 12 from the light-emitting surface 12S and is interfered with (e.g., reflected back by) a target object. For ease of understanding, hereinafter, the light leaving the light-emitting element 12 may be referred to as the first light, and the light interfered with (e.g., reflected back by) a target object may be referred to as the second light. In some embodiments, the light-emitting element 12 may include a light-emitting diode, such as an organic light-emitting diode (OLED), a mini LED, a micro LED, or a quantum dot LED, but the present disclosure is not limited thereto.

In some embodiments, the light-emitting element 12 includes an active layer, and the wavelength from the first light emitted by the light-emitting element 12 depends on the material composition from the active layer. For example, when the active layer is or includes an InGaN series material, the light-emitting element 12 may emit blue light or deep blue light having a peak wavelength from 400 nm to 490 nm, or green light having a peak wavelength from 490 nm to 550 nm; when the active layer is or includes an AlGaN series material, the light-emitting element 12 may emit ultraviolet light having a peak wavelength from 250 nm to 400 nm; when the active layer is or includes an InGaAs series, InGaAsP series, AlGaAs series, or AlGaInAs series material, the light-emitting element 12 may emit infrared light having a peak wavelength from 700 nm to 1700 nm; when the active layer is or includes an InGaP series or AlGaInP series material, the light-emitting element 12 may emit red light having a peak wavelength from 610 nm to 700 nm, or yellow light having a peak wavelength from 530 nm to 600 nm. It should be noted that the above-mentioned color lights are only examples, and the light-emitting element 12 may also emit invisible light, such as infrared light or ultraviolet light.

As shown in FIG. 1, continuing from the above steps, a light-receiving element 13 is disposed on the integrated circuit 11, wherein the light-receiving element 13 has a light-receiving surface 13S. Specifically, the light-receiving element 13 is configured to receive the second light, wherein the second light enters the light-receiving element 13 through the light-receiving surface 13S to generate a corresponding sensing current. In some embodiments, the light-receiving element 13 may include a photoresistor, a photodiode, a light-emitting diode, a combination thereof, or other suitable elements, but the present disclosure is not limited thereto. In some embodiments, the light-receiving element 13 is embedded in or integrated into the integrated circuit 11. In other words, the light-receiving element 13 does not protrude from the integrated circuit 11. Alternatively, the light-receiving element 13 may be a part of the integrated circuit 11 and formed in the same process as the integrated circuit 11. In this case, the light-receiving surface 13S of the light-receiving element 13 is coplanar with the upper surface of the integrated circuit 11.

In some embodiments, the light-receiving element 13 includes an optoelectronic conversion layer, which is configured to convert light of a specific wavelength into an electrical signal. For example, the optoelectronic conversion layer may convert blue light and dark blue light having a peak wavelength of 400 nm to 490 nm into an electrical signal; convert green light having a peak wavelength of 490 nm to 550 nm into an electrical signal; convert ultraviolet light having a peak wavelength of 250 nm to 400 nm into an electrical signal; convert infrared light having a peak wavelength of 700 nm to 1700 nm into an electrical signal; convert red light having a peak wavelength of 610 nm to 700 nm ; or convert yellow light having a peak wavelength of 530 nm to 600 nm into an electrical signal, but the present disclosure is not limited thereto. It should be noted that the above-mentioned wavelength range is only an example, and the light-receiving element 13 may also receive invisible light, such as infrared light or ultraviolet light.

As shown in FIG. 1, continuing from the above steps, a first light-blocking part 14 is disposed on the integrated circuit 11, wherein the first light-blocking part 14 is located between the light-emitting surface 12S of the light-emitting element 12 and the light-receiving surface 13S of the light-receiving element 13, and extends across the entire integrated circuit 11. Specifically, the first light-blocking part 14 may be configured to shield light to prevent the light-receiving element 13 from receiving laterally incident light (i.e., the first light). In addition, the first light-blocking part 14 may also be used as a sacrificial layer or a stop layer to protect the integrated circuit 11 located thereunder from damage during a subsequent dicing process of the encapsulation body.

In some embodiments, the first light-blocking part 14 may include silicone, epoxy resin, polyphthalamide (PPA), polychlorinated biphenyl (PCB), copper foil, aluminum foil, a combination thereof, or other suitable materials, but the present disclosure is not limited thereto. In some embodiments, the first light-blocking part 14 may be provided by a dispensing process, a coating process, a pick and press process, a combination thereof, or other suitable processes, but the present disclosure is not limited thereto. In some embodiments, the visible light transmittance of the first light-blocking part 14 is less than 5%, but the present disclosure is not limited thereto. For example, the visible light transmittance of the first light-blocking part 14 may be 5%, 4%, 3%, 2%, 1%, 0.1%, or any value or range between the above values. In other embodiments, the infrared light transmittance of the first light-blocking part 14 is less than 5%, or the ultraviolet light transmittance is less than 5%. In some embodiments, the shape of the first light-blocking part 14 may be cylindrical as shown in FIG. 1, but the present disclosure is not limited thereto. In other embodiments, the shape of the first light-blocking part 14 may also be a triangular column, a quadrilateral column, a polygonal column, an irregular column, or other suitable shapes, but the present disclosure is not limited thereto.

In some embodiments, the height h1 of the first light-blocking part 14 is between 0.1 mm and 1.5 mm, but the present disclosure is not limited thereto. For example, the height h1 may be 0.1 mm, 0.15 mm, 0.2 mm, 0.3 mm, 0.5 mm, 0.6 mm, 1.5 mm, or any value or range between the above values. When the height h1 is less than 0.1 mm, the first light-blocking part 14 may fail to provide sufficient protection for the integrated circuit 11. Conversely, when the height h1 is greater than 1.5 mm, the first light-blocking part 14 may occupy excessive space within the package structure, which may adversely affect the miniaturization of the device.

In some embodiments, the width w1 of the first light-blocking part 14 is between 0.05 mm and 2 mm, but the present disclosure is not limited thereto. For example, the width w1 may be 0.05 mm, 0.08 mm, 0.1 mm, 0.12 mm, 0.15 mm, 0.3 mm, 0.8 mm, 1 mm, 1.5 mm, 2 mm, or any value or range between the above values. When the width w1 is less than 0.05 mm, the first light-blocking part 14 may fail to provide enough space to set the second light-blocking part 18, which causes the margin of the dicing process to decrease. Conversely, when the width w1 is greater than 2 mm, the first light-blocking part 14 may occupy excessive space within the package structure, which may adversely affect the miniaturization of the device.

In some embodiments, the distance d1 between the first light-blocking part 14 and the light-emitting element 12 is between 0.1 mm and 4 mm, but the present disclosure is not limited thereto. For example, the distance d1 may be 0.1 mm, 0.5 mm, 1 mm, 1.2 mm, 1.5 mm, 2 mm, 2.2 mm, 3 mm, 4 mm, or any value or range between the above values. When the distance d1 is less than 0.1 mm, the first light-blocking part 14 may be too close to the light-emitting element 12, which results in a reduction in the margin of the dicing process. Conversely, when the distance d1 is greater than 4 mm, the first light-blocking part 14 may occupy excessive space within the package structure, which may adversely affect the miniaturization of the device.

In some embodiments, the distance d2 between the first light-blocking part 14 and the light-receiving element 13 is between 0.1 mm and 4 mm, but the present disclosure is not limited thereto. For example, the distance d2 may be 0.1 mm, 0.5 mm, 1 mm, 1.2 mm, 1.5 mm, 2 mm, 2.2 mm, 3 mm, 4 mm, or any value or range between the above values. When the distance d2 is less than 0.1 mm, the first light-blocking part 14 may be too close to the light-receiving element 13, which results in a reduction in the margin of the dicing process. Conversely, when the distance d2 is greater than 4 mm, the first light-blocking part 14 may occupy excessive space in the package structure, which may adversely affect the miniaturization of the device.

As shown in FIG. 1, continuing from the above steps, a first electrical connection member 15 is provided to electrically connect the light-emitting element 12 and the substrate 10, and a second electrical connection member 16 is provided to electrically connect the integrated circuit 11 and the substrate 10. In some embodiments, the first electrical connection member 15 or the second electrical connection member 16 may be or may include various electrical connection members such as a wire, solder, silver paste, redistribution layer (RDL), pin, or pad.

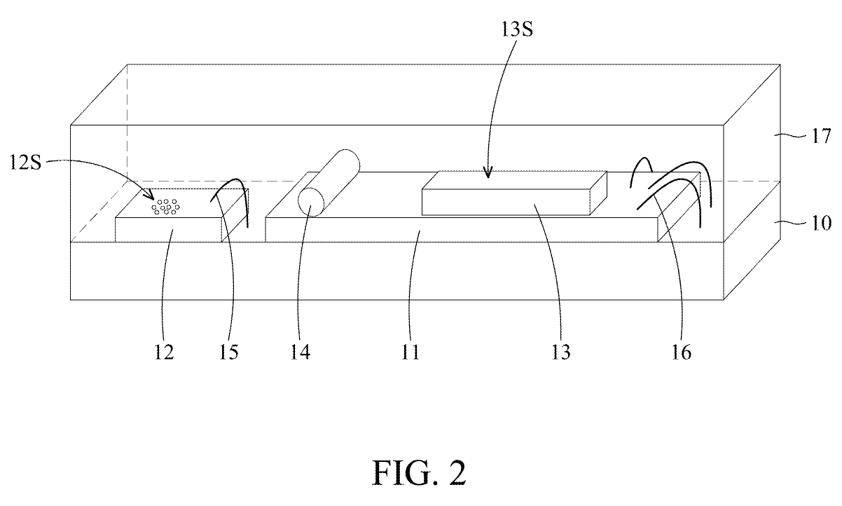

As shown in FIG. 2, continuing from the above steps, an encapsulation body 17 is disposed on the substrate 10 to completely or partially cover the integrated circuit 11, the light-emitting element 12, the light-receiving element 13, and the first light-blocking part 14, wherein the encapsulation body 17 covers the light-emitting surface 12S of the light-emitting element 12 and the light-receiving surface 13S of the light-receiving element 13. Specifically, the encapsulation body 17 is configured to protect the light-emitting element 12 and the light-receiving element 13 from damaged by dust and moisture. Therefore, in some embodiments, the encapsulation body 17 may further cover a plurality of side surfaces of the light-emitting element 12 and/or a plurality of side surfaces of the light-receiving element 13 to provide more comprehensive protection for the light-emitting element 12 and the light-receiving element 13.

In some embodiments, the encapsulation body 17 may include a polymer material, a combination thereof, or other suitable materials, but the present disclosure is not limited thereto. For example, the polymer material may be or may include epoxy resin, polyimide (PI), polypropylene (PP), a combination thereof, or other suitable polymer materials, but the present disclosure is not limited thereto. In some embodiments, the encapsulation body 17 may have a rectangular shape as shown in FIG. 2, but the present disclosure is not limited thereto. In other embodiments, the encapsulation body 17 may also have a trapezoidal shape, a polygonal shape, or any other suitable shape.

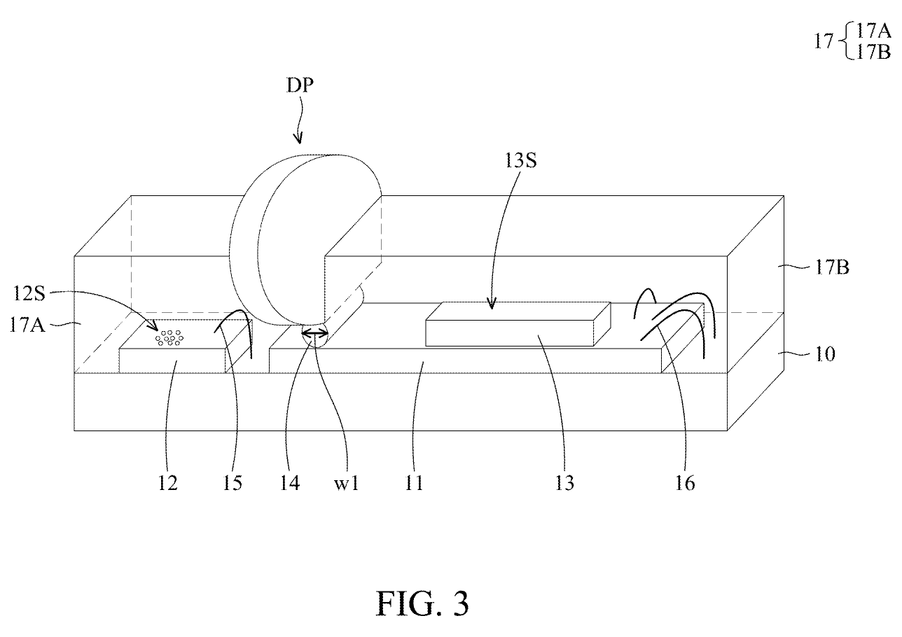

As shown in FIG. 3, continuing from the above steps, the first light-blocking part 14 is used as a sacrificial layer or a stop layer, and a dicing process DP is performed on the encapsulation body 17, so that the encapsulation body 17 is divided into a first encapsulating part 17A and a second encapsulating part 17B. The light-emitting element 12 is located within the first encapsulating part 17A, the light-receiving element 13 is located within the second encapsulating part 17B, and the first light-blocking part 14 is disposed between the first encapsulating part 17A and the second encapsulating part 17B. In some embodiments, the dicing process DP may be implemented by a blade, laser, etching, a combination thereof, or other suitable processes, but the present disclosure is not limited thereto. In some embodiments where a blade is used for the dicing process DP, the width of the blade may be smaller than the width w1 of the first light-blocking part 14 to increase the margin of the dicing process DP.

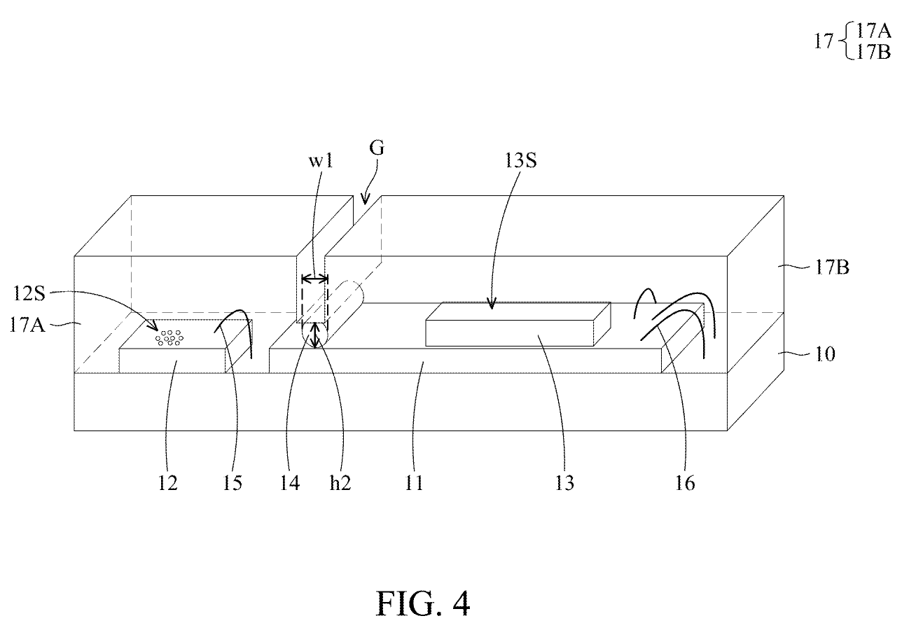

As shown in FIG. 4, continuing from the above steps, after the dicing process DP is performed, a gap G is formed between the first encapsulating part 17A and the second encapsulating part 17B. In some embodiments, the width of the gap G may be equal to the width of the blade. In other words, the width of the gap G may be smaller than the width w1 of the first light-blocking part 14. In some embodiments, the height h2 of the first light-blocking part 14 after the dicing process DP is performed is smaller than the height h1 before the dicing process DP is performed. In other words, a portion of the first light-blocking part 14 may be removed during the dicing process DP, but the present disclosure is not limited thereto.

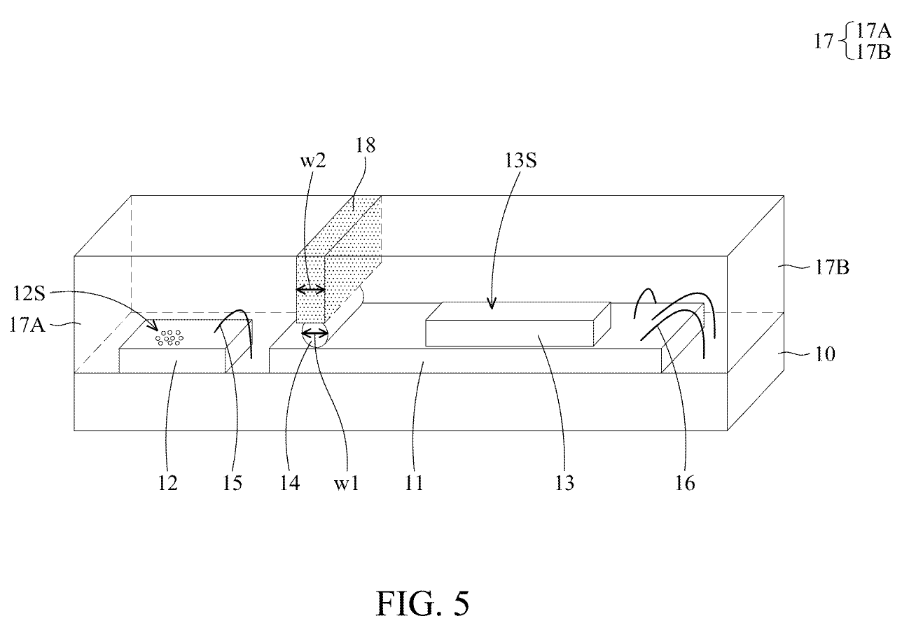

As shown in FIG. 5, a second light-blocking part 18 is disposed on the first light-blocking part 14 that is exposed from the gap G, wherein the first light-blocking part 14 and the second light-blocking part 18 are located between the first encapsulating part 17A and the second encapsulating part 17B and extend across the entire integrated circuit 11. Specifically, the second light-blocking part 18 may be directly disposed on the first light-blocking part 14 and cooperatively with the first light-blocking portion 14, configured to block light, so as to prevent the light-receiving element 13 from receiving laterally incoming light (i.e., the first light), thereby avoiding erroneous detection.

In some embodiments, the second light-blocking part 18 may include silicone, epoxy resin, PPA, PCB, copper foil, aluminum foil, a combination thereof, or other suitable materials, but the present disclosure is not limited thereto. In some embodiments, the second light-blocking part 18 may be formed by a dispensing process, a coating process, a pick-and-press process, a combination thereof, or other suitable processes, but the present disclosure is not limited thereto. In some embodiments, the material of the first light-blocking part 14 may be different from the material of the second light-blocking part 18. Alternatively, the second light-blocking part 18 may be an air gap. That is, the second light-blocking part 18 may be a non-solid space filled with gas (e.g., air). In this case, the total reflection of light may be achieved by adjusting the refractive index ratio between the encapsulation body 17 and the gas within the second light-blocking part 18. For example, the refractive index ratio between the encapsulation body 17 and the gas located in the second light-blocking part 18 may be between 0.8 :1 and 2 :1, for example, 0.8:1, 1.3:1, 1.6:1, 2:1, or any value or range between the above values, but the present disclosure is not limited to this.

In some embodiments, the visible light transmittance of the second light-blocking part 18 is less than 5%, but the present disclosure is not limited thereto. For example, the visible light transmittance of the second light-blocking part 18 may be 5%, 4%, 3%, 2%, 1%, 0.1%, or any value or range between the above values. In other embodiments, the infrared light transmittance of the second light-blocking part 18 is less than 5%, or the ultraviolet light transmittance is less than 5%. In some embodiments, the second light-blocking part 18 may have a rectangular block shape as shown in FIG. 5, but the present disclosure is not limited thereto. In other embodiments, the shape of the first light-blocking part 14 may also be a polygonal block, an irregular block, or any other suitable shape, but the present disclosure is not limited thereto.

In some embodiments, the width w2 of the second light-blocking part 18 is between 0.05 mm and 1 mm, but the present disclosure is not limited thereto. For example, the width w2 may be 0.05 mm, 0.15 mm, 0.08 mm, 0.2 mm, 1 mm, or any value or range between the above values. In some embodiments, the width w1 of the first light-blocking part is different from the width w2 of the second light-blocking part, for example, the width w1 may be less than, equal to, or greater than the width w2.

By the above configuration, the present disclosure provides the package structure, which includes the substrate 10, an integrated circuit 11, the light-emitting element 12, the light-receiving element 13, the first light-blocking part 14, the second light-blocking part 18, and an encapsulation body 17. Specifically, the integrated circuit 11 is disposed on the substrate 10. The light-emitting element 12 is disposed on the substrate 10 and has the light-emitting surface 12S. The light-receiving element 13 is disposed on the integrated circuit 11 and has the light-receiving surface 13S. The first light-blocking part 14 is disposed on the integrated circuit 11 and is located between the light-emitting surface 12S of the light-emitting element 12 and the light-receiving surface 13S of the light-receiving element 13. The second light-blocking part 18 is disposed on the first light-blocking part 14. The encapsulation body 17 is disposed on the light-emitting element 12 and the light-receiving element 13.

In the following, various embodiments of the package structure will be further provided to more fully illustrate the technology disclosed herein. For the sake of simplicity, the same reference numerals are used in the following description and drawings to refer to the same or similar elements, and repetitive descriptions will be omitted accordingly.

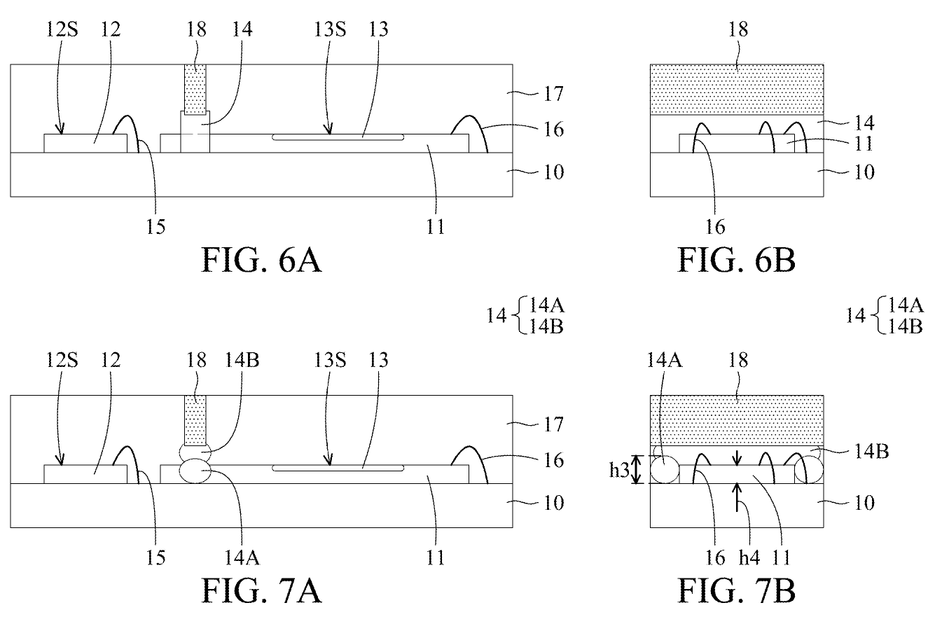

FIGS. 6A and 6B are respectively a cross-sectional view and another cross-sectional view illustrating the package structure according to other embodiments of the present disclosure. More specifically, FIG. 6A is a cross-sectional view taken along the longitudinal axis of the package structure, and FIG. 6B is a cross-sectional view taken along the transverse axis of the package structure. As shown in FIG. 6B, in some embodiments, the width of the integrated circuit 11 is less than the width of the substrate 10. In this case, the first light-blocking part 14 may extend across the entire integrated circuit 11 and cover the two side surfaces of the integrated circuit 11. In other words, the first light-blocking part 14 may have an inverted U-shaped configuration, instead of the columnar shape as illustrated in FIG. 5.

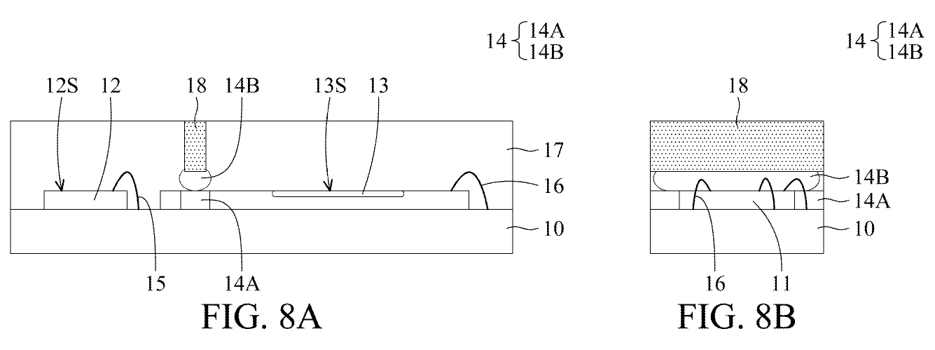

FIGS. 7A and 7B are respectively a cross-sectional schematic views and another cross-sectional schematic view illustrating the package structure according to still other embodiments of the present disclosure. More specifically, FIG. 7A is a cross-sectional view taken along the longitudinal axis of the package structure, and FIG. 7B is a cross-sectional view taken along the transverse axis of the package structure. As shown in FIG. 7A, in some embodiments, the width of the integrated circuit 11 is less than the width of the substrate 10. In this case, a first sub-blocking part 14A may be provided on both sides of the integrated circuit 11. Specifically, the first sub-blocking parts 14A are configured to support other components formed thereon, such as second sub-blocking parts 14B to be subsequently provided. Then, a second sub-blocking part 14B is provided on the first sub-blocking part 14A and the integrated circuit 11, wherein the first sub-blocking part 14A and the second sub-blocking part 14B together form the first light-blocking part 14.

In some embodiments, the material of the first sub-blocking part 14A may be similar or the same as that of the second sub-blocking part 14B, but the present disclosure is not limited thereto. In some embodiments, the first sub-blocking part 14A may have a higher mechanical strength than the second sub-blocking part 14B to more effectively support the second sub-blocking part 14B. In some embodiments, the second sub-blocking part 14B may have a lower visible light transmittance (or invisible light transmittance) than the first sub-blocking part 14A, thereby preventing the light-receiving element 13 from receiving the first light.

In some embodiments, the shape of the first sub-blocking part 14A may have a round sphere shape as shown in FIG. 7B, but the present disclosure is not limited thereto. In other embodiments, the shape of the first sub-blocking part 14A may also be an elliptical sphere, a polygonal block, or any other suitable shape. In some embodiments, the height h3 of the first sub-blocking part 14A may be greater than the height h4 of the integrated circuit 11, but the present disclosure is not limited thereto. In some embodiments, the height h3 of the first sub-blocking part 14A may also be equal to or less than the height h4 of the integrated circuit 11.

In some embodiments, in a top view or a cross-sectional view, the width of the first sub-blocking part 14A may be greater than the width of the second sub-blocking part 14B to better support the second sub-blocking part 14B thereon. For example, the width of the first sub-blocking part 14A may be 110%, 120%, 130%, 140%, 150% of the width of the second sub-blocking part 14B, or any value or range between the above values, but the present disclosure is not limited thereto.

In some embodiments, the shape of the second sub-blocking part 14B may be an elliptical cylinder as shown in FIG. 7B, but the present disclosure is not limited thereto. In other embodiments, the shape of the second sub-blocking part 14B may also be a rectangular cylinder, a polygonal block, or any other suitable shape. In the embodiment where the first sub-blocking part 14A and the second sub-blocking part 14B have the shape as shown in FIG. 6B, a light-blocking dielectric material may further be filled around the first sub-blocking part 14A and the second sub-blocking part 14B to prevent the first light from passing through any gap between the two components.

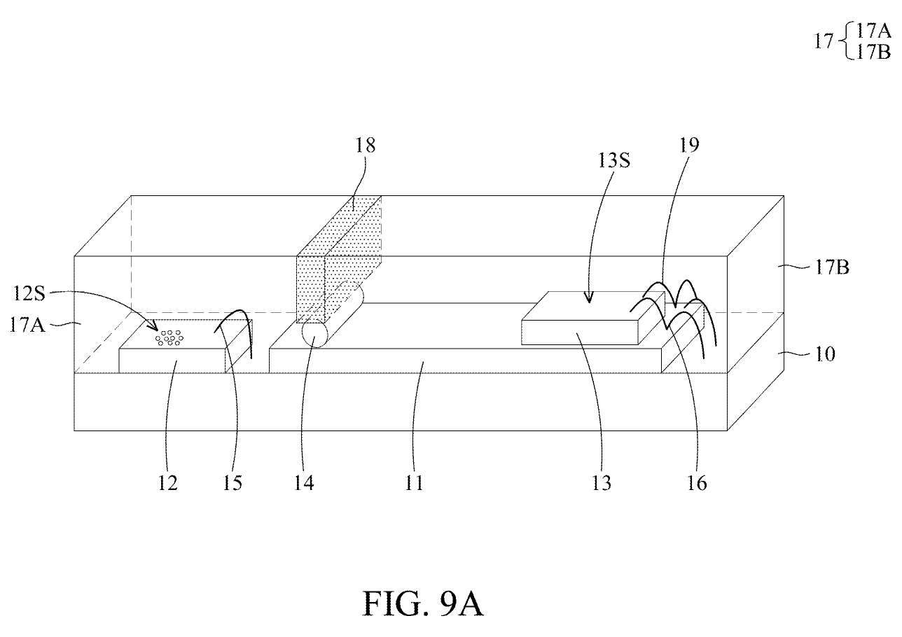

FIGS. 8A and 8B are respectively a cross-sectional schematic view and another cross-sectional schematic view illustrating the package structure according to further embodiments of the present disclosure. More specifically, FIG. 8A is a cross-sectional view taken along the longitudinal axis of the package structure, and FIG. 8B is a cross-sectional view taken along the transverse axis of the package structure. As shown in FIG. 8B, in some embodiments, the first sub-blocking part 14A may have a rectangular block shape, which facilitates better coverage of the side surfaces of the integrated circuit 11 and improved support for the second sub-blocking part 14B. In other words, the present disclosure allows for adjusting the specific shape of the first sub-blocking part 14A or the specific shape of the second sub-blocking part 14B based on design requirements, so as to selectively cover all or part (e.g., a specific portion) of the side surfaces of the integrated circuit 11.

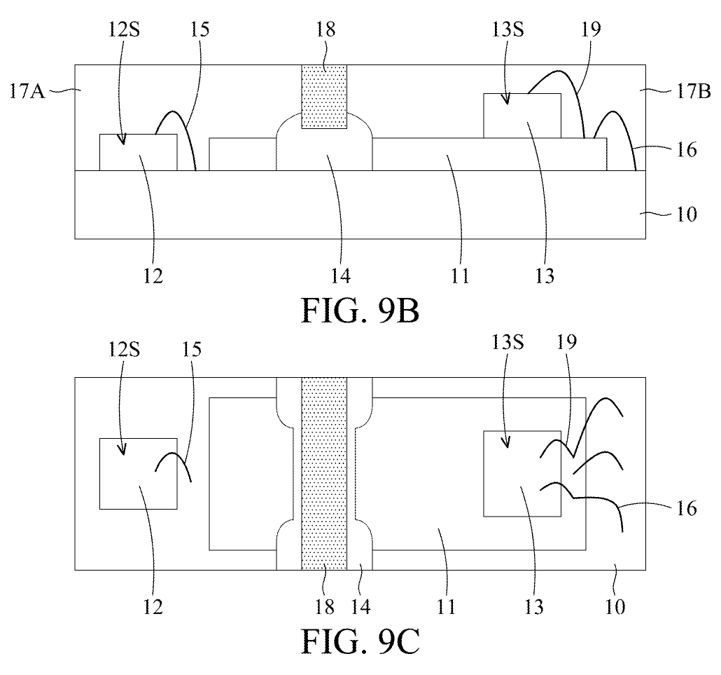

FIGS. 9A to 9C are respectively a perspective schematic view, a side view schematic view, and a top view schematic view illustrating the package structure according to still other embodiments of the present disclosure. As shown in FIG. 9A, in some embodiments, the light-receiving element 13 protrudes from the integrated circuit 11. In other words, the light-receiving element 13 may not be integrated into the integrated circuit 11, but may be independently disposed on the integrated circuit 11. In this case, the light-receiving surface 13S of the light-receiving element 13 is not coplanar with the upper surface of the integrated circuit 11. In some embodiments, the package structure further includes a third electrical connection member 19, and the third electrical connection member 19 electrically connects the light-receiving element 13 and the integrated circuit 11. Similarly, the third electrical connection member 19 may also be or may include various electrical connection members such as wires, solder, silver paste, redistribution structure, gaskets, pins, etc.

As shown in FIG. 9B and FIG. 9C, in the cross-sectional view or the top view, the width w1 of the first light-blocking part 14 is greater than the width w2 of the second light-blocking part 18. In addition, the width w1 of the first light-blocking part 14 may gradually decrease from the upper and lower edges of the substrate 10 toward the central region, thereby forming a “dumbbell-shaped” structure. However, the present disclosure is not limited thereto, and the shape of the first light-blocking part 14 may be determined based on design requirements.

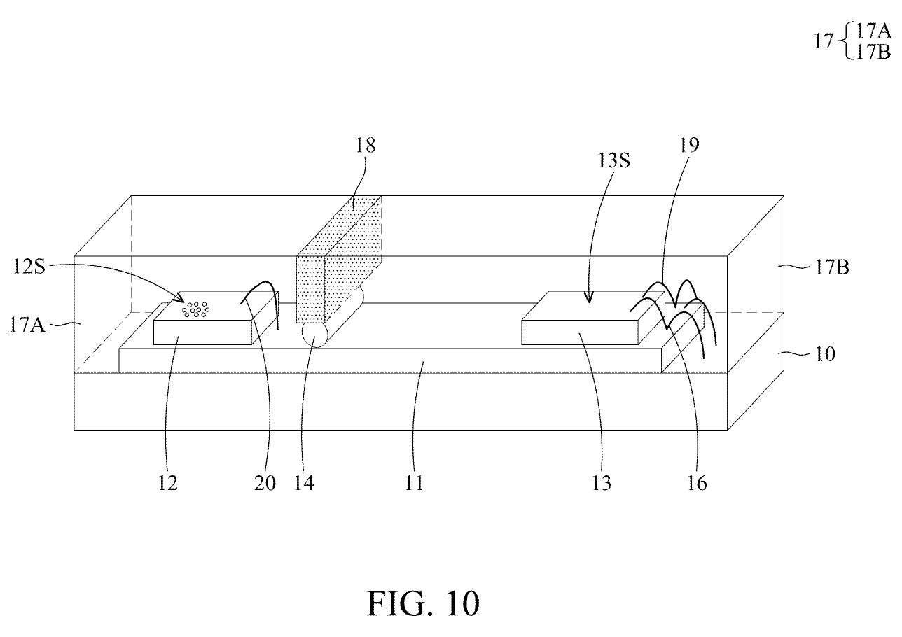

FIG. 10 is a perspective schematic view illustrating the package structure according to further embodiments of the present disclosure. As shown in the figure, in some embodiments, the integrated circuit 11 may extend to the bottom of the light-emitting element 12. In other words, the light-emitting element 12 is disposed on the integrated circuit 11 and protrudes from the integrated circuit 11. In this case, the light-emitting surface 12S of the light-emitting element 12 is not coplanar with the upper surface of the integrated circuit 11. In some embodiments, the package structure further includes a fourth electrical connection member 20, and the fourth electrical connection member 20 electrically connects the light-emitting element 12 and the integrated circuit 11. Similarly, the fourth electrical connection member 20 may also be or may include various electrical connection members such as wires, solder, silver paste, redistribution structure, gaskets, pins, etc. In addition, in the embodiment shown in FIG. 10, the light-receiving element 13 is embedded in or integrated into the integrated circuit 11. In other words, the light-receiving element 13 does not protrude from the integrated circuit 11.

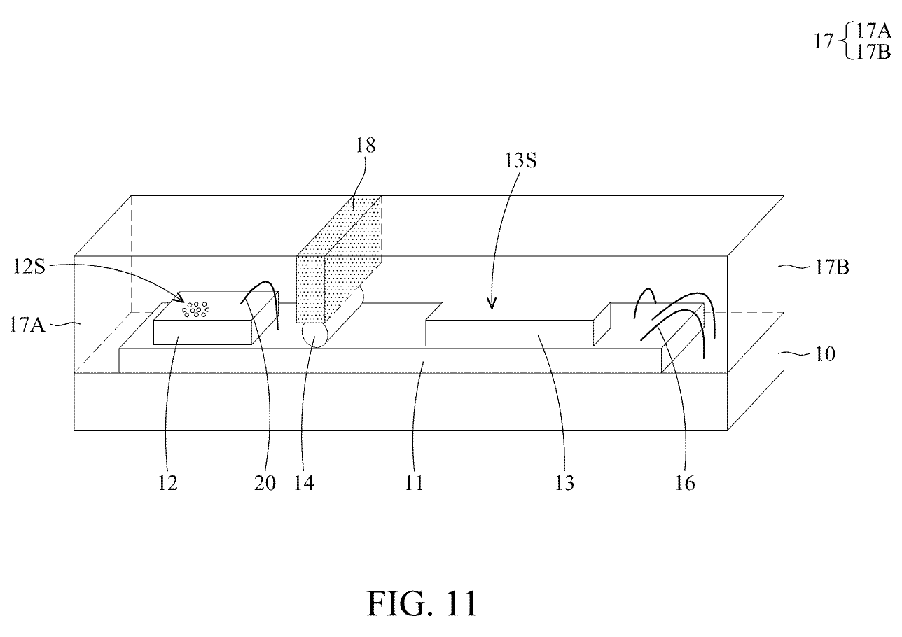

FIG. 11 is a perspective schematic view illustrating the package structure according to still other embodiments of the present disclosure. As shown in the figure, in some embodiments, the light-emitting element 12 is disposed on the integrated circuit 11 and protrudes from the integrated circuit 11, and the light-receiving element 13 is embedded in or integrated into the integrated circuit 11 and does not protrude from the integrated circuit 11. In other words, the light-emitting element 12 and the light-receiving element 13 of the present disclosure may be optionally independently disposed on the substrate 10 or the integrated circuit 11 based on design requirements, or may be optionally integrated into or embedded in the integrated circuit 11.

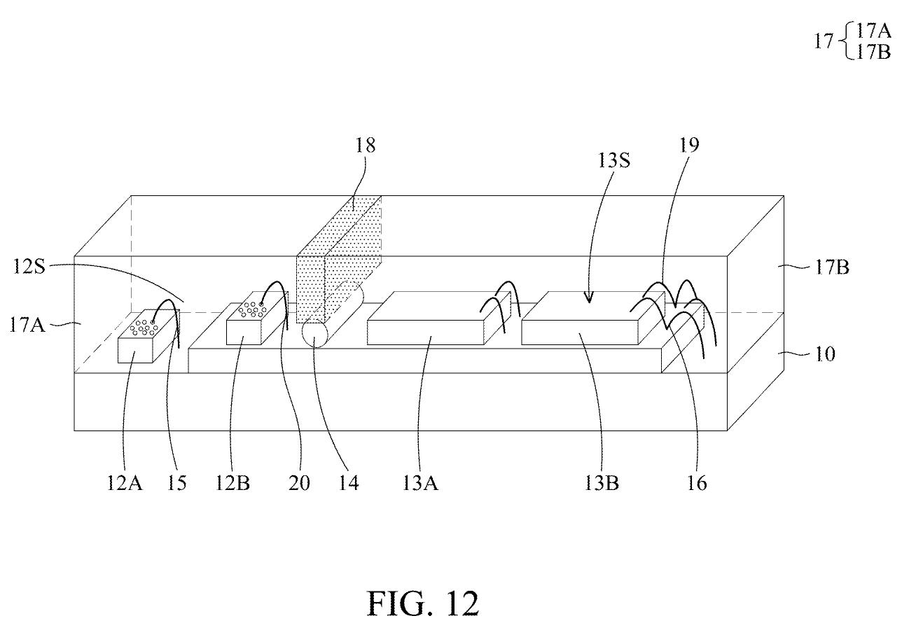

FIG. 12 is a perspective schematic view illustrating the package structure according to another embodiments of the present disclosure. As shown in the figure, in some embodiments, a plurality of light-emitting elements 12 is provided. For example, the light-emitting element 12 may include a first light-emitting element 12A and a second light-emitting element 12B, but the present disclosure is not limited thereto. The first light-emitting element 12A and the second light-emitting element 12B may be disposed on the substrate 10 or on the integrated circuit 11 based on design requirements. For example, the first light-emitting element 12A may be disposed on the substrate 10, and the second light-emitting element 12B may be disposed on the integrated circuit 11.

Similarly, in some embodiments, a plurality of light-receiving elements 13 is provided. For example, the light-receiving element 13 may include a first light-receiving element 13A and a second light-receiving element 13B, but the present disclosure is not limited thereto. The first light-receiving element 13A and the second light-receiving element 13B may be disposed on the integrated circuit 11 or integrated (embedded) in the integrated circuit 11 based on design requirements. For example, the first light-receiving element 13A and the second light-receiving element 13B may both be disposed on the integrated circuit 11.

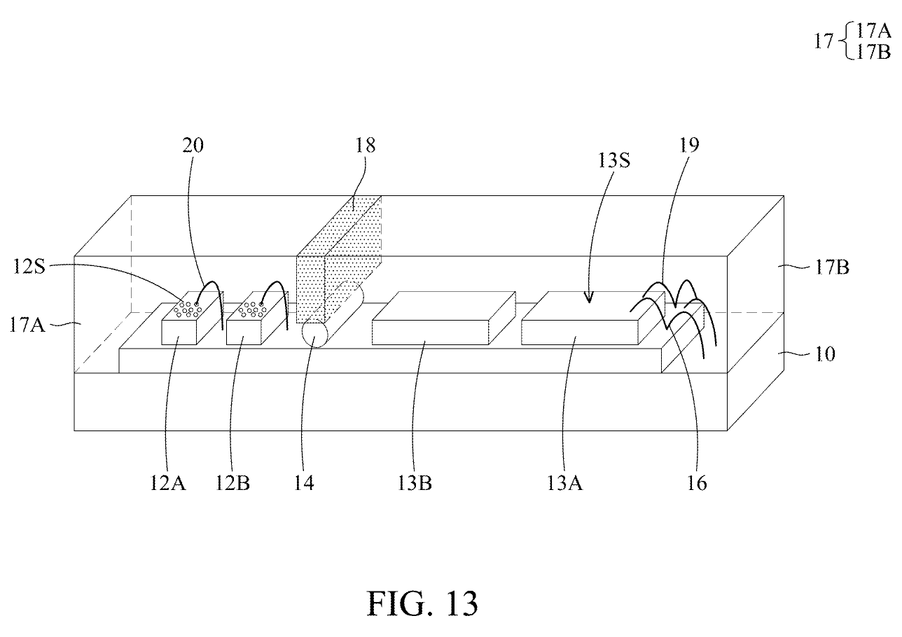

FIG. 13 is a perspective schematic view illustrating the package structure according to another embodiment of the present disclosure. As shown in the figure, in some embodiments, the first light-receiving element 13A and the second light-receiving element 13B may be disposed on the integrated circuit 11 or integrated (embedded) in the integrated circuit 11 based on design requirements. For example, the first light-receiving element 13A and the second light-receiving element 13B may be disposed on the integrated circuit 11, and the second light-receiving element 13B may be integrated (embedded) in the integrated circuit 11.

In summary, the present disclosure provides a package structure that reduces the specific distance required between the dicing position and the light-emitting element as well as the light-receiving element by disposing a sacrificial layer or a blocking layer, thereby simplifying the manufacturing process and reducing the size of the device.

In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a substrate;
an integrated circuit, disposed on the substrate;
a light-emitting element, disposed on the substrate, and having a light-emitting surface;
a light-receiving element, disposed on the integrated circuit, and having a light-receiving surface;
a first light-blocking part, disposed on the integrated circuit, and located between the light-emitting surface and the light-receiving surface;
a second light-blocking part, disposed on the first light-blocking part; and
an encapsulation body, disposed on the light-emitting element and the light-receiving element.

2. The package structure as claimed in claim 1, wherein the encapsulation body partially or completely covers the light-emitting surface and the light-receiving surface.

3. The package structure as claimed in claim 1, wherein the encapsulation body comprises:
a first encapsulating part, covering the light-emitting element; and
a second encapsulating part, covering the light-receiving element,
wherein the first light-blocking part and the second light-blocking part are disposed between the first encapsulating part and the second encapsulating part.

4. The package structure as claimed in claim 1, wherein the encapsulation body covers a plurality of side surfaces of the light-emitting element, a plurality of side surfaces of the light-receiving element, or both thereof.

5. The package structure as claimed in claim 1, wherein the light-emitting element is disposed on the integrated circuit.

6. The package structure as claimed in claim 1, wherein the light-receiving element is embedded in the integrated circuit.

7. The package structure as claimed in claim 6, wherein the integrated circuit has an upper surface which is coplanar with the light-receiving surface.

8. The package structure as claimed in claim 1, further comprising a first light-emitting element disposed on the substrate.

9. The package structure as claimed in claim 8, further comprising a second light-emitting element disposed on the integrated circuit.

10. The package structure as claimed in claim 1, further comprising a first light-receiving element disposed on the integrated circuit.

11. The package structure as claimed in claim 10, further comprising a second light-receiving element disposed on the integrated circuit.

12. The package structure as claimed in claim 1, wherein the first light-blocking part has a first width, the second light-blocking part has a second width different from the first width.

13. The package structure as claimed in claim 1, wherein the first light-blocking part, the second light-blocking part, or both thereof comprise silicone, epoxy resin, polyphthalamide (PPA), polychlorinated biphenyl (PCB), copper foil, aluminum foil, or a combination thereof.

14. The package structure as claimed in claim 1, wherein the second light-blocking part is an air gap.

15. The package structure as claimed in claim 1, wherein the first light-blocking part comprises:
a first sub-blocking part; and
a second sub-blocking part disposed on the first sub-blocking part.

16. The package structure as claimed in claim 15, wherein the first sub-blocking part covers at least a portion of a side surface of the integrated circuit.

17. The package structure as claimed in claim 15, wherein in a top view, a width of the first sub-blocking part is greater than a width of the second sub-blocking part.

18. The package structure as claimed in claim 15, wherein the first sub-blocking part and the second sub-blocking part comprise a same material.

19. The package structure as claimed in claim 15, wherein, in a cross-sectional view, the first sub-blocking part has a first height, the integrated circuit has a second height smaller than the first height.

20. The package structure as claimed in claim 1, further comprising:
a first electrical connection member electrically connecting the light-emitting element and the substrate; and
a second electrical connection member electrically connecting the integrated circuit and the substrate.
